(19) United States
(12) Patent Application Publication
(10) Pub. No.: US 2026/0159402 A1
(43) Pub. Date: Jun. 11, 2026

(54) NEGATIVE ACTIVE MATERIAL AND RECHARGEABLE LITHIUM BATTERY INCLUDING SAME

(71) Applicant: SAMSUNG SDI CO., LTD., Yongin-si (KR)

(72) Inventors: Yookyung KIM, Yongin-si (KR); Eunji KANG, Yongin-si (KR); Youngugk KIM, Yongin-si (KR)

(73) Assignee: SAMSUNG SDI CO., LTD., Yongin-si (KR)

(21) Appl. No.: 19/182,192

(22) Filed: Apr. 17, 2025

(30) Foreign Application Priority Data
Apr. 18, 2024 (KR) 10-2024-0052360

(51) Int. Cl. C01B 33/02; C23C 16/24; H01M 4/02; H01M 4/36; H01M 4/38; H01M 4/583; H01M 10/0525

(52) U.S. Cl. CPC C01B 33/02; C23C 16/24; H01M 4/366; H01M 4/386; H01M 4/583; H01M 10/0525; C01P 2004/50; C01P 2004/62; C01P 2004/84; C01P 2006/40; H01M 2004/021; H01M 2004/027

(57) ABSTRACT

Disclosed are a negative active material, and a rechargeable lithium battery including the negative active material. The negative active material includes crystalline silicon primary particles, amorphous silicon, and an amorphous carbon coating layer.

### CROSS-REFERENCE TO RELATED APPLICATION

This application claims the benefit of priority to Korean Patent Application No. 10-2024-0052360 filed in the Korean Intellectual Property Office on Apr. 18, 2024, the entire contents of which are incorporated herein by reference.

### BACKGROUND

### (a) Field

Example embodiments relate to a negative active material, and a rechargeable lithium battery including the negative active material.

### (b) Description of the Related Art

With increasing use of electronic devices that use batteries such as, e.g., mobile phones, laptop computers, and electric vehicles, demand for smaller, lighter and relatively high-capacity rechargeable lithium batteries is increasing. Improving performances of rechargeable lithium batteries may thus be advantageous.

Rechargeable lithium batteries typically include a positive electrode and a negative electrode including an active material capable of intercalating and deintercalating lithium ions, and an electrolyte solution, and electrical energy is produced by oxidation and reduction reactions when lithium ions are intercalated/deintercalated at the positive and negative electrodes.

### SUMMARY

One or more example embodiments include a negative active material exhibiting high-capacity, high efficiency, and desired or improved cycle-life characteristic.

Another example embodiment includes a rechargeable lithium battery including the negative active material.

One or more example embodiments include a negative active material including crystalline silicon primary particle; amorphous silicon; and an amorphous carbon coating layer.

Another example embodiment includes a rechargeable lithium battery including a negative electrode including the negative active material; a positive electrode; and an electrolyte.

A negative active material according to one or more example embodiments may exhibit high-capacity, high efficiency, and desired or improved cycle-life characteristic.

### BRIEF DESCRIPTION OF THE DRAWINGS

FIG. 1 is a schematic view showing the negative active material according to one or more example embodiments.

FIG. 2 to FIG. 5 are a cross-sectional view schematically illustrating rechargeable lithium batteries, according to some example embodiment.

### DETAILED DESCRIPTION

Hereinafter, example embodiments are described in detail. However, these example embodiments are exemplary, the present disclosure is not limited thereto and the present disclosure is defined by the scope of claims.

Terms used in the specification explain example embodiments, but are not intended limit the present disclosure. Expressions in the singular include expressions in plural unless the context clearly dictates otherwise.

The term “combination thereof” may include a mixture, a laminate, a complex, a copolymer, an alloy, a blend, a reactant of constituents.

The term “comprise,” “include” or “have” are intended to designate that the performed characteristics, numbers, step, constituted elements, or a combination thereof is present, but it should be understood that the possibility of presence or addition of one or more other characteristics, numbers, steps, constituted element, or a combination thereof are not to be precluded in advance.

The drawings show that the thickness is enlarged in order to clearly show the various layers and regions, and the same reference numerals are given to similar parts throughout the specification. When an element, such as a layer, a film, a region, a plate, and the like is referred to as being “on” or “over” another part, it may include cases where it is “directly on” another element, but also cases where there is another element in between. In contrast, when an element is referred to as being “directly on” another element, there are no intervening elements present.

Herein, “layer” includes a shape totally formed on the entire surface or a shape formed on a partial surface, when viewed from a plane view.

Herein, “or” is not to be construed as an exclusive meaning, for example, “A or B” is construed to include A, B, A+B, and the like.

As used herein, when a definition is not otherwise provided, a particle diameter or a particle size may be an average particle diameter. The average particle diameter indicates an average value of the diameter of the particles depending on a cumulative volume in the particle size distribution of particles included in the negative active material. The average particle diameter (D50) ay be measured by a method well known to those skilled in the art, for example, by a particle size analyzer, or by a transmission electron microscopic image, or a scanning electron microscopic image.

In some example embodiments, a dynamic light-scattering measurement device is used to perform a data analysis, and the number of particles is counted for each particle size range, and from this, the average particle diameter (D50) value may be readily obtained through a calculation.

In some example embodiments, an average particle diameter may be measured by various techniques, and for example, may be measured by a particle size analyzer.

In some example embodiments, a thickness may be measured by a SEM or a TEM image for the cross-section, but is not limited thereto, and it may be measured by any techniques, as long as it may measure the thickness in the related arts. The thickness may be an average thickness.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

As used herein, soft carbon refers to graphitizable carbon materials and are readily graphitized by heat treatment at a high temperature, e.g., about 2800° C., and hard carbon refers to non-graphitizable carbon materials and are substantially nor or slightly graphitized by heat treatment. The terms “soft carbon” and “hard carbon” may be well known in the related arts.

In some example embodiments, the crystalline carbon and the amorphous carbon may be distinguished through XRD measurement. The crystalline carbon includes natural graphite and artificial graphite. Natural graphite may indicate graphite which may be naturally generated by separation from minerals, and when measured by XRD, the interplanar spacing (d002) of the (002) plane may be in a range of about 3.350 Å to about 3.360 Å. Artificial graphite may indicate graphite manufactured by graphitization, and if (e.g., when) measured by XRD, the interplanar spacing (d002) of the (002) plane may be in a range of about 3.355 Å to about 3.365 Å. For example, the amorphous carbon may have the interplanar spacing (d 002) of the (002) plane of about 3.34 Å or less, when measured by XRD. The XRD may be measured using CuKα ray as a target ray with an X-ray diffraction analyzer (e.g., product name: X'Pert, manufacturer: Malvern Panalytical) and by removing a monochromator to improve a peak density resolution. The measurement condition may be 2θ=10° to 80°, a scan speed (°/S) of 0.044 to 0.089, and a step size (°/step) of 0.013 to 0.039.

A negative active material according to one or more example embodiments includes crystalline silicon primary particles; amorphous silicon; and an amorphous carbon coating layer.

In one or more example embodiments, the amorphous silicon may be located on a surface of the crystalline silicon primary particles, and for example, the amorphous silicon may be located surrounding the surface of the crystalline silicon primary particles. For example, the amorphous silicon is located surrounding the surface of the crystalline silicon primary particles, and thus, the surface of the crystalline silicon primary particles may be coated with amorphous silicon, and the amorphous silicon may be included in the form of layer that is substantially continuously covering the surface of the crystalline silicon primary particles.

The position of amorphous silicon on the surface of the crystalline silicon primary particles may slowly convert the crystalline silicon primary particles to the amorphous silicon during charging and discharging, thereby enhancing the charge and discharge efficiency. As the amorphous silicon with low volume expansion surrounds the surface of the crystalline silicon primary particles, volume expansion of the negative active material during charging and discharging may be reduced or suppressed. This may reduce or prevent deterioration during charging and discharging, thereby improving a cycle-life characteristic. The negative active material includes amorphous silicon with a relatively larger critical size than crystalline silicon, and thus, charging and discharging may occur easier.

In one or more example embodiments, the amorphous carbon coating layer may be located so as to surround the crystalline silicon primary particles and the amorphous silicon. If the amorphous silicon surrounds the surface of the crystalline silicon primary particles, the amorphous carbon coating layer may be located on the amorphous silicon, thereby surrounding amorphous silicon.

In one or more example embodiments, if the crystalline silicon primary particles and the amorphous silicon positioned on the surface of the primary particles are referred to as a core, the amorphous carbon coating layer may be located on the surface of the core and may be filled inside of the core. For example, the amorphous carbon coating layer may be located between the primary particles, and may surround the surface of the amorphous silicon, and thus, may enable a dense form with almost no space inside the core.

In one or more example embodiments, the crystalline silicon primary particles may be agglomerated to prepare secondary particles. For example, the negative active material according to one or more example embodiments may include secondary particles where at least one or more crystalline silicon primary particles are agglomerated. Herein, the amorphous silicon may be located on the surface of the secondary particles to coat the surface of the secondary particles. For example, the amorphous silicon may be in the form of a layer surrounding the surface of the secondary particles.

The amorphous carbon coating layer may be configured to surround the amorphous silicon.

For example, the negative active material according to one or more example embodiments may include secondary particles where at least one or more crystalline silicon primary particles are agglomerated, the amorphous carbon is located on the surface of the secondary particle, and the amorphous carbon coating layer surround the secondary particles and the amorphous silicon. If the amorphous silicon is covering the secondary particle, the amorphous carbon coating layer may be located on the amorphous silicon.

The amorphous carbon coating layer may be located between the secondary particles, surrounding the surface of the amorphous silicon, and thus, the inside of the negative active material may become dense. For example, if the secondary particles and the amorphous silicon positioned on the surface of the secondary particles are referred to as a core, the amorphous carbon coating layer is filled inside the core, and is positioned on the amorphous silicon, thereby providing a negative active material with a dense form having substantially almost no empty space inside.

As such, inclusion of the amorphous silicon and the amorphous carbon coating layer may provide the negative active material with a dense interior, thereby improving cycle-life characteristic.

A porosity of the negative active material according to one or more example embodiments may be in a range of greater than 0% to about 3%, greater than 0% to about 1.75%, or about 0.20% to about 1.00%. In one or more example embodiments, the porosity may be determined by measuring a volume of pores through the BJH (Barrett-Joyner-Halenda) technique and dividing the measured pore volume by the total volume of the active material.

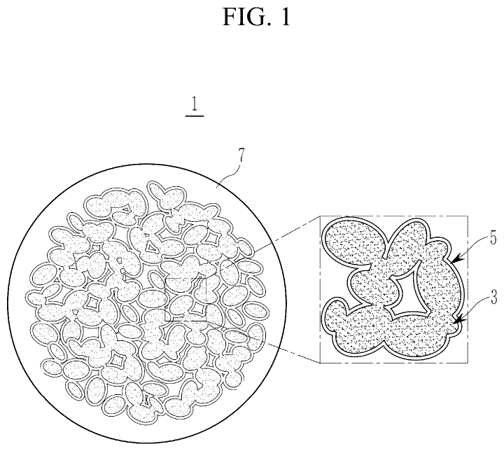

FIG. 1 shows the schematic structure of the negative active material. In FIG. 1, the negative active material 1 includes secondary particles where the crystalline silicon primary particles 3 are agglomerated and the amorphous silicon 5 covering the surface of the secondary particles. The negative active material 1 further includes amorphous carbon coating layer 7 substantially completely surrounding the secondary particles and the amorphous silicon 5.

In one or more example embodiments, the amorphous Si may be confirmed by measuring TEM or X-ray diffraction peak (XRD). In case of measuring TEM, Si exhibiting no crystal lattice stripes may be referred to as amorphous silicon. In the case of measuring an XRD using a CuKα ray as a target ray, the appearance of a broad peak may refer to amorphous silicon.

The negative active material according to one or more example embodiments includes both crystalline silicon and amorphous silicon, and thus, both sharp crystalline peaks and broad amorphous peaks may appear in the XRD measurement.

In one or more example embodiments, a mixing ratio of the crystalline silicon primary particles and the amorphous silicon may be in a range of about 95:5 to about 20:80 by weight ratio, about 85:15 to about 40:60 by weight ratio, or about 70:30 to about 50:50 by weight ratio. If the mixing ratio of the crystalline silicon primary particles and the amorphous silicon satisfies the range, the characteristics of the crystalline silicon and the amorphous silicon may both simultaneously or contemporaneously be improved, resulting in high capacity and further improved efficiency and cycle-life.

In one or more example embodiments, an amount of the amorphous silicon may be, based on 100 wt % of the negative active material, in a range of about 1 wt % to about 50 wt %, about 5 wt % to about 40 wt %, or about 15 wt % to about 30 wt %. If the amount of the amorphous silicon is within any of the above ranges, the efficiency and the cycle-life may be more enhanced, along with high-capacity.

An amount of the crystalline silicon primary particles may be, based on 100 wt % of the negative active material, in a range of about 30 wt % to about 80 wt %, about 40 wt % to about 70 wt %, or about 45 wt % to about 60 wt %. If the amount of the crystalline silicon primary particles is within any of the above ranges, the high-capacity may be maintained, and further enhanced efficiency and cycle-life characteristic may be exhibited. In one or more example embodiments, the secondary particles are an agglomerated product where the crystalline silicon primary particles are agglomerated, and thus, the amount of the primary particles is substantially identical to the amount of the secondary particles.

In one or more example embodiments, an amount of the amorphous carbon may be, based on 100 wt % of the negative active material, in a range of about 19 wt % to about 65 wt %, about 25 wt % to about 60 wt %, or about 30 wt % to about 55 wt %. The amount of the amorphous carbon is an amount of the amorphous carbon coating layer, and may be the total amount of the amorphous carbon included in the negative active material.

In one or more example embodiments, the average particle diameter (D50) of the crystalline silicon primary particles may be in a range of about 50 nm to about 150 nm, about 60 nm to about 120 nm, or about 70 nm to about 100 nm. If the average particle diameter (D50) of the crystalline silicon primary particles is within any of the above ranges, desired or improved cycle-life attributes may be obtained. In the negative active material according to one or more example embodiments, the average particle diameter (D50) of the crystalline silicon primary particles is important, and the particle diameter of the secondary particle may be appropriately adjusted. In one or more example embodiments, the average particle diameter (D50) may be measured by the above-mentioned technique, and e.g., may be measured by a particle size analyzer.

In the amorphous carbon coating layer, amorphous carbon may be or include at least one of pitch carbon, soft carbon, hard carbon, mesophase pitch carbide, sintered coke, carbon fiber, or a combination thereof.

In one or more example embodiments, a thickness of the amorphous carbon coating layer may be in a range of more than 0 nm and about 2 μm or less, about 1 nm to about 2000 nm, or about 1 nm to about 1000 nm. The thickness indicates a thickness of the amorphous carbon on the surface of the core. If amorphous carbon is unevenly located, the thickness may indicate a length of the thickest amorphous carbon. In one or more example embodiments, the thickness may be an average thickness. If the thickness of the amorphous carbon coating layer is within the range, the charge and discharge efficiency and rate characteristic may be more enhanced.

The amorphous silicon may be prepared by a vapor deposition. The vapor deposition will be illustrated in the following description.

The negative active material according to one or more example embodiments may be prepared by the following procedures.

Silicon nano particles are prepared. This silicon nano particles may have a particle diameter in a range of about 10 nm to about 200 nm.

Such silicon nano particles may be obtained by performing the general procedures for preparing nano particles such as, e.g., a pulverization, or the like. The pulverization may be carried out by adding a dispersant to mix. The dispersant may be or includes at least one of stearic acid, polyvinyl pyrrolidone, polyvinyl alcohol, polyacrylic acid, gallic acid, carboxymethyl cellulose, sucrose, ethylene glycol, citric acid, boron nitride (BN), MgS or a combination thereof.

The mixing may be carried out by using a bead mill or a ball mill. If the dispersant is mixed, the dispersant may be present in an amount suitable for the silicon nano particles to be substantially dispersed in a solvent. For example, the mixing ratio of the dispersant and the silicon nano particles may be in a range of about 30:70 to about 90:10 by weight ratio, about 40:60 to about 90:10 by weight ratio.

The resulting product is dried. The drying may be carried out by, e.g., spray drying. If the drying is carried out by spray drying, a dried product with substantially uniform particle diameters may be prepared, and secondary particles where silicon nano particles (primary particles) are agglomerated, may be prepared.

The drying may be carried out at a temperature in a range of about 100° C. to about 200° C., or about 120° C. to about 170° C.

Therefore, a vapor deposition is conducted on the resulting dried product using a Si-included gas to form amorphous silicon on a surface of the dried product. The amorphous silicon may be positioned to cover the surface of the dried product.

The vapor deposition may be a chemical vapor deposition (CVD). The chemical vapor deposition may be any one or more of thermal chemical vapor deposition, plasma-enhanced chemical vapor deposition, or low pressure chemical vapor deposition.

The Si-included gas may be or include at least one of a SiH₄ gas, a Si₂H₆ gas, a Si₃H₈ gas, or a combination thereof.

The vapor deposition may be performed at a temperature at which deposited silicon is converted into amorphous Si (a-Si), and for example, vapor deposition may be performed at a temperature in a range of about 300° C. to about 700° C., or about 400° C. to about 600° C. If the vapor deposition is performed at a temperature of more than about 700° C., silicon to be deposited may become crystallized, thereby increasing the volume expansion during charge and discharge, and deteriorating the cycle-life characteristics, which is undesirable. If vapor deposition is performed at a temperature of less than about 300° C., the silicon raw material is typically not readily decomposed and remains as silicon raw material, becoming an impurity in the porous supporter, which is also undesirable.

In the vapor deposition, the flow rate of gas, which is the Si-included gas, may be in a range of about 1 sccm to about 1000 sccm, about 10 sccm to about 700 sccm, or about 50 sccm to about 500 sccm. The sccm is standard cc per minute and indicates gas flow rate at which molecular particles of 2.7×10¹⁹ per minute and is measured value at about 0° C. and about 1 atm. By the process, silicon may be filled between the crystalline silicon primary particles.

The deposition may be carried out for a period in a range of about 10 minutes to about 5 hours, about 20 minutes to about 4 hours, about 20 minutes to about 3 hours, or about 20 minutes to about 1 hour.

Thereafter, an amorphous carbon coating layer is formed on the resulting product. The formation of the amorphous carbon coating layer is carried out by vapor coating with an amorphous carbon precursor gas, or by mixing the resulting product with the amorphous carbon precursor, and carbonizing.

The amorphous carbon precursor gas may be or include at least one of a methane (CH₄) gas, an ethylene (C₂H₄) gas, an acetylene (C₂H₂) gas, a propane (C₃H₈) gas, a propylene (C₃H₆) gas, or a combination thereof. The vapor coating may be carried out by a vapor deposition, and the vapor deposition may be a chemical vapor deposition. The vapor deposition procedure may be carried out at a temperature in a range of about 400° C. to about 1000° C., or about 500° C. to about 700° C.

The amorphous carbon precursor may be or include at least one of petroleum coke, coal coke, petroleum pitch, coal pitch, pitch carbon, mesocarbon pitch, green cokes, or a combination thereof.

If the resulting product is mixed with the amorphous carbon precursor, a mixing ratio of the product and the amorphous carbon precursor may be in a range of about 80:20 by weight ratio to about 35:65 by weight ratio, about 75:25 by weight ratio to about 40:60 by weight ratio, or about 70:30 to about 45:55 by weight ratio.

The carbonization may be carried out at a temperature in a range of about 500° C. to about 1,000° C., or about 600° C. to about 900° C. In the carbonization, the dispersant may be removed. The carbonization may be carried out at an N₂ atmosphere, a helium atmosphere, or a combination thereof.

In the heat-treatment, the amorphous carbon precursor may be converted into an amorphous carbon, thereby including an amorphous carbon in the negative active material. This amorphous carbon may be positioned surrounding the crystalline silicon primary particles and the amorphous silicon, and may be filled inside by insertion in the pores formed between the amorphous silicon and between the crystalline silicon primary particles.

The amorphous carbon may be arranged so as to surround the secondary particles where the crystalline silicon primary particles are agglomerated, and the amorphous silicon on the surface of the secondary particles, and may be filled inside by insertion in the pores formed between the amorphous silicon, or between the secondary particles.

According to the carbon coating, an amorphous carbon coating layer is formed on the surface of the secondary particles.

### Rechargeable Lithium Battery

Another example embodiment includes a rechargeable lithium battery including the negative electrode, a positive electrode, and an electrolyte.

### Negative Electrode:

The negative electrode includes a current collector and a negative active material layer formed on the current collector and including the negative active material according to one or more example embodiments. The negative active material layer includes the negative active material and may further include a binder and/or a conductive material.

The negative active material according to one or more example embodiments is included as a first negative active material, and crystalline carbon may be included as a second negative active material. A mixing ratio of the first negative active material to the second negative active material may be in a range of about 20:80 to about 10:90 by weight ratio. In other example embodiments, the negative active material may include the first negative active material and the second negative active material at a weight ratio in a range of about 85:15 to about 90:10.

In the negative active material layer, an amount of the negative active material may be in a range of about 90 wt % to about 99 wt % based on the total 100 wt % of the negative active material layer. An amount of the binder may be in a range of about 1 wt % to about 5 wt % based on the total 100 wt % of the negative active material layer. If the conductive material is further included, an amount of the binder may be in a range of about 0.5 wt % to about 5 wt % based on the total 100 wt % of the active material layer, and an amount of the conductive material may be in a range of about 0.5 wt % to about 5 wt % based on the total 100 wt % of the active material layer.

The binder improves binding properties of negative active material particles with one another and with a current collector. The binder may be or include a non-aqueous binder, an aqueous binder, a dry binder or combination thereof.

The non-aqueous binder may be or include at least one of polyvinyl chloride, carboxylated polyvinyl chloride, polyvinyl fluoride, an ethylene propylene copolymer, polystyrene, polyurethane, polytetrafluoroethylene, polyvinylidene fluoride, polyethylene, polypropylene, polyamideimide, polyimide, or a combination thereof.

The aqueous binder may be or include at least one of a styrene-butadiene rubber, a (meth) acrylated styrene-butadiene rubber, a (meth)acrylonitrile-butadiene rubber, a (meth)acryl rubber, a butyl rubber, a fluorine rubber, polyethylene oxide, polyvinylpyrrolidone, polyepichlorohydrin, polyphosphazene, poly(meth)acrylonitrile, an ethylene propylene diene copolymer, polyvinyl pyridine, chlorosulfonated polyethylene, latex, a polyester resin, a (meth)acrylic resin, a phenol resin, an epoxy resin, polyvinyl alcohol, or a combination thereof.

If the aqueous binder is a negative electrode binder, a cellulose-based compound may be further added to provide viscosity. The cellulose-based compound includes one or more of carboxymethyl cellulose, hydroxypropylmethyl cellulose, methyl cellulose, or alkali metal salts thereof. The alkali metal may be or include at least one of Na, K, or Li.

The dry binder may be or include a polymer material that is capable of being fibrous. For example, the dry binder may be or include at least one of polytetrafluoroethylene, polyvinylidene fluoride, a polyvinylidene fluoride-hexafluoropropylene copolymer, polyethylene oxide, or a combination thereof.

The conductive material is included to provide electrode conductivity, and any electrically conductive material may be a conductive material unless the electrically conductive material causes a chemical change in the battery. Examples of the conductive material may be or include a carbon-based material such as or including at least one of natural graphite, artificial graphite, carbon black, acetylene black, ketjen black, a carbon fiber, a carbon nanofiber, carbon nanotube, or the like; a metal-based material of a metal powder or a metal fiber including at least one of copper, nickel, aluminum, silver, and the like; a conductive polymer such as a polyphenylene derivative; or a mixture thereof.

The negative current collector may include one or more of a copper foil, a nickel foil, a stainless steel foil, a titanium foil, a nickel foam, a copper foam, a polymer substrate coated with a conductive metal, and a combination thereof.

### Positive Electrode:

The positive electrode may include a current collector and a positive electrode active material layer on the current collector. The positive active material layer includes a positive active material, and may further include a binder and/or a conductive material.

For example, the positive electrode may further include an additive that may be a sacrificial positive electrode.

An amount of the positive active material may be in a range of about 90 wt % to about 99.5 wt % based on 100 wt % of the positive active material layer, and amounts of the binder and the conductive material may be respectively 0.5 wt % to 5 wt % based on 100 wt % of the positive active material layer.

The positive active material may include a compound (lithiated intercalation compound) that is capable of intercalating and deintercalating lithium. In some example embodiments, at least one of a composite oxide of lithium and a metal including at least one of cobalt, manganese, nickel, or combinations thereof may be used.

The composite oxide may be or include a lithium transition metal composite oxide, and examples thereof may include at least one of lithium nickel-based oxide, lithium cobalt-based oxide, lithium manganese-based oxide, lithium iron phosphate-based compound, cobalt-free nickel-manganese-based oxide, or a combination thereof.

For example, the following compounds represented by any one of the following chemical formulas may be used. LiₐA_{1-b}X_{b}O_{2-c}D_{c} (0.90≤a≤1.8, 0≤b≤0.5, 0≤c≤0.05); LiₐMn_{2-b}X_{b}O_{4-c}D_{c} (0.90≤a≤1.8, 0≤b≤0.5, 0≤c≤0.05); LiₐNi_{1-b-c}Co_{b}X_{c}O_{2-α}D_{α} (0.90≤a≤1.8, 0≤b≤0.5, 0≤c≤0.5, 0<α<2); LiₐNi_{1-b-c}Mn_{b}X_{c}O_{2-α}D_{α} (0.90≤a≤1.8, 0≤b≤0.5, 0≤c≤0.5, 0<α<2); LiₐNi_{b}Co_{c}L¹_{d}GₑO₂ (0.90≤a≤1.8, 0≤b≤0.9, 0≤c≤0.5, 0≤d≤0.5, 0≤e≤0.1); LiₐNiG_{b}O₂ (0.90≤a≤1.8, 0.001≤b≤0.1); LiₐCoG_{b}O₂ (0.90≤a≤1.8, 0.001≤b≤0.1); LiₐMn_{1-b}G_{b}O₂ (0.90≤a≤1.8, 0.001≤b≤0.1); LiₐMn₂G_{b}O₄ (0.90≤a≤1.8, 0.001≤b≤0.1); LiₐMn_{1-g}G_{g}PO₄ (0.90≤a≤1.8, 0≤g≤0.5); Li_{(3-f)}Fe₂(PO₄)₃ (0≤f≤2); LiₐFePO₄ (0.90≤a≤1.8).

In the above chemical formulas, A is or includes at least one of Ni, Co, Mn, or a combination thereof; X is or includes at least one of Al, Ni, Co, Mn, Cr, Fe, Mg, Sr, V, a rare earth element or a combination thereof; D is or includes at least one of O, F, S, P, or a combination thereof; G is or includes at least one of Al, Cr, Mn, Fe, Mg, La, Ce, Sr, V, or a combination thereof; and L¹ is or includes at least one of Mn, Al, or a combination thereof.

For example, the positive active material may be or include a high nickel-based positive active material having a nickel amount of greater than or equal to about 80 mol %, greater than or equal to about 85 mol %, greater than or equal to about 90 mol %, greater than or equal to about 91 mol %, or greater than or equal to about 94 mol % and less than or equal to about 99 mol % based on 100 mol % of the metal excluding lithium in the lithium transition metal composite oxide. The high-nickel-based positive active material may realize high capacity and may be applicable to a high-capacity, high-density rechargeable lithium battery.

The binder improves binding properties of positive active material particles with one another and with a current collector. Examples of the binder may be or include at least one of polyvinyl alcohol, carboxymethyl cellulose, hydroxypropyl cellulose, diacetyl cellulose, polyvinyl chloride, carboxylated polyvinyl chloride, polyvinyl fluoride, an ethylene oxide-containing polymer, polyvinyl pyrrolidone, polyurethane, polytetrafluoroethylene, polyvinylidene fluoride, polyethylene, polypropylene, a styrene butadiene rubber, a (meth)acrylated styrene butadiene rubber, an epoxy resin, a (meth)acrylic resin, a polyester resin, nylon, or the like, but are not limited thereto.

The conductive material is included to provide electrode conductivity, and any electrically conductive material may be a conductive material unless the electrically conductive material causes a chemical change in the battery. Examples of the conductive material may include a carbonaceous material such as at least one of natural graphite, artificial graphite, carbon black, acetylene black, Ketjen black, carbon fiber, carbon nanofiber, carbon nanotube, or the like; a metal-based material of a metal powder or a metal fiber including at least one of copper, nickel, aluminum, silver, or the like; a conductive polymer such as a polyphenylene derivative; or a mixture thereof.

The current collector may include Al, but is not limited thereto.

### Electrolyte:

The electrolyte includes a non-aqueous organic solvent and a lithium salt.

The non-aqueous organic solvent may be or include a medium for transmitting ions taking part in the electrochemical reaction of a battery.

The non-aqueous organic solvent may include at least one of a carbonate-based, ester-based, ether-based, ketone-based, alcohol-based, or aprotic solvent.

The carbonate-based solvent may include at least one of dimethyl carbonate (DMC), diethyl carbonate (DEC), dipropyl carbonate (DPC), methylpropyl carbonate (MPC), ethylpropyl carbonate (EPC), methylethyl carbonate (MEC), ethylene carbonate (EC), propylene carbonate (PC), butylene carbonate (BC), or the like.

The ester-based solvent may include at least one of methyl acetate, ethyl acetate, n-propyl acetate, dimethyl acetate, methyl propionate, ethyl propionate, decanolide, mevalonolactone, valerolactone, caprolactone, or the like.

The ether-based solvent may include at least one of dibutyl ether, tetraglyme, diglyme, dimethoxyethane, 2-methyltetrahydrofuran, 2,5-dimethyltetrahydrofuran, tetrahydrofuran, or the like. The ketone-based solvent may include cyclohexanone, or the like. The alcohol-based solvent may include ethanol, isopropyl alcohol, and the like and the aprotic solvent may include at least one of nitriles such as R-CN (wherein R is a C2 to C20 linear, branched, or cyclic hydrocarbon group, and may include a double bond, an aromatic ring, or an ether bond, and the like); amides such as dimethylformamide; dioxolanes such as 1,3-dioxolane, 1,4-dioxolane, and the like; sulfolanes, or the like.

The non-aqueous organic solvent may be present alone or in a mixture of two or more solvents.

When the carbonate-based solvent is used, the cyclic carbonate and the linear carbonate may be mixed together therewith, and the cyclic carbonate and the linear carbonate may be mixed at a volume ratio in a range of about 1:1 to about 1:9.

In an example, the lithium salt dissolved in an organic solvent supplies a battery with lithium ions, substantially operates the rechargeable lithium battery, and improves transportation of the lithium ions between positive and negative electrodes. Examples of the lithium salt include one or at least two supporting electrolyte salt such as at least one of LiPF₆, LiBF₄, LiSbF₆, LiAsF₆, LiClO₄, LiAlO₂, LiAlCl₄, LiPO₂F₂, LiCl, LiI, LiN(SO₃C₂F₅)₂, Li(FSO₂)₂N (lithium bis(fluorosulfonyl)imide, LiFSI), LiC₄F₉SO₃, LiN(CₓF₂ₓ₊₁SO₂)(C_{y}F_{2y+1}SO₂), where x and y are an integer of 1 to 20, lithium trifluoromethane sulfonate, lithium tetrafluoroethane sulfonate, lithium difluorobis(oxalato)phosphate (LiDFBOP), lithium bis(oxalato) borate (LiBOB).

### Separator:

A separator may be disposed between the positive electrode and the negative electrode depending on a type of a rechargeable lithium battery. The separator may use polyethylene, polypropylene, polyvinylidene fluoride or multi-layers thereof having two or more layers, and may be or include at least one of a mixed multilayer such as a polyethylene/polypropylene double-layered separator, a triple-layered separator, a polyethylene/polypropylene/polyethylene polypropylene/polyethylene/polypropylene triple-layered separator, and the like.

The separator may include a porous substrate and a coating layer including an organic material, an inorganic material, or a combination thereof on one or both surfaces of the porous substrate.

The porous substrate may be or include a polymer film formed of or including any one or more of polyolefin such as polyethylene and polypropylene, polyester such as polyethylene terephthalate and polybutylene terephthalate, polyacetal, polyamide, polyimide, polycarbonate, polyether ketone, polyarylether ketone, polyetherimide, polyamideimide, polybenzimidazole, polyethersulfone, polyphenylene oxide, a cyclic olefin copolymer, polyphenylene sulfide, polyethylene naphthalate, a glass fiber, TEFLON, and polytetrafluoroethylene, or a copolymer or mixture of two or more thereof.

The organic material may include a polyvinylidene fluoride-based polymer or a (meth)acryl-based polymer.

The inorganic material may be or include an inorganic particle including at least one of Al₂O₃, SiO₂, TiO₂, SnO₂, CeO₂, MgO, NiO, CaO, GaO, ZnO, ZrO₂, Y₂O₃, SrTiO₃, BaTiO₃, Mg(OH)₂, boehmite, or a combination thereof, but is not limited thereto.

The organic material and an inorganic material may be mixed in one coating layer, or a coating layer including an inorganic material and a coating layer including an organic material may be stacked.

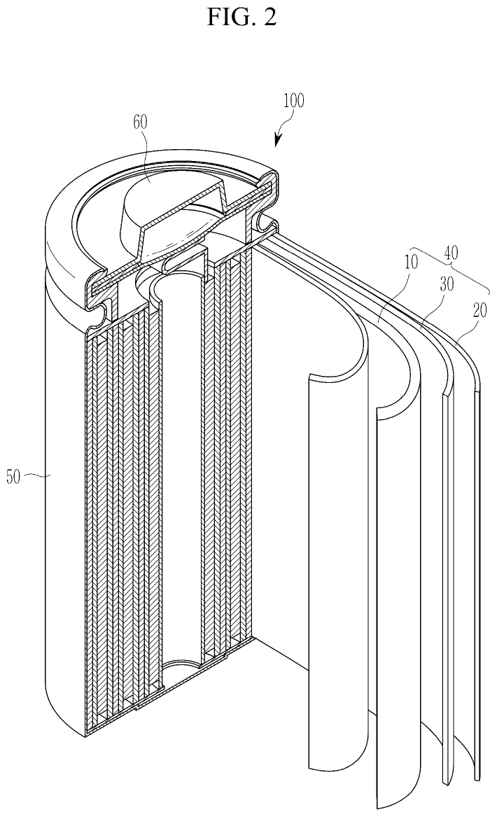

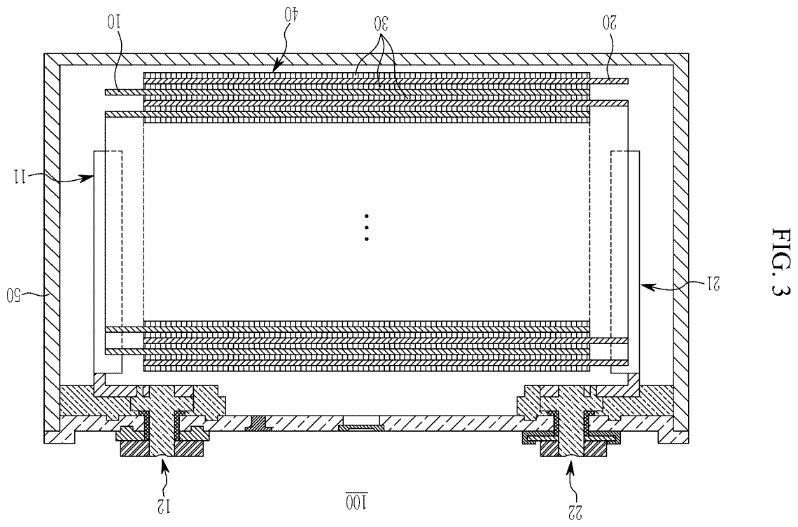

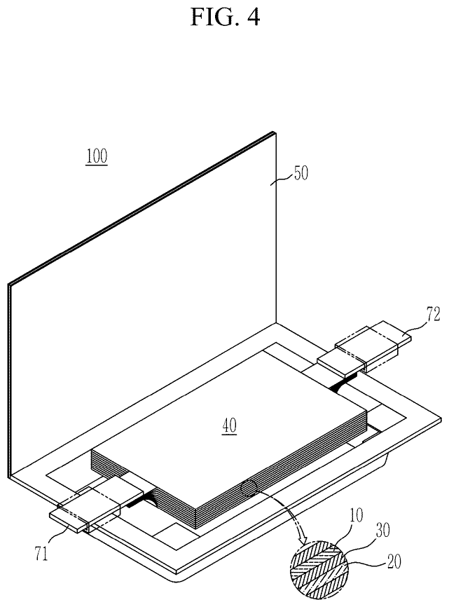

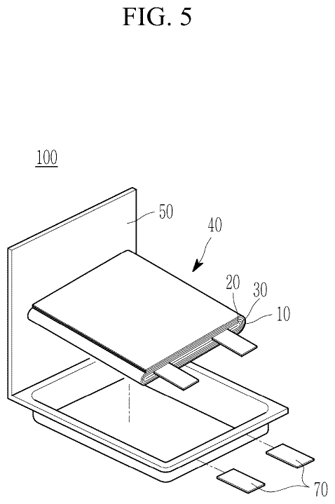

The rechargeable lithium battery may be classified into cylindrical, prismatic, pouch, or coin-type batteries, and the like depending on their shape. FIG. 2 to FIG. 5 are schematic views illustrating a rechargeable lithium battery, according to an example embodiment. FIG. 2 illustrates a cylindrical battery, FIG. 3 illustrates a prismatic battery, and FIG. 4 and FIG. 5 illustrate pouch-type batteries. Referring to FIGS. 2 to 5, the rechargeable lithium battery 100 may include an electrode assembly 40 including a separator 30 between a positive electrode 10 and a negative electrode 20, and a case 50 in which the electrode assembly 40 is included. The positive electrode 10, the negative electrode 20, and the separator 30 may be impregnated with an electrolyte (not shown). The rechargeable lithium battery 100 may include a sealing member 60 sealing the case 50, as shown in FIG. 2. In FIG. 3, the rechargeable lithium battery 100 may include a positive electrode lead tab 11 and a positive terminal 12, a negative electrode lead tab 21, and a negative terminal 22. As shown in FIG. 4 and FIG. 5, the rechargeable lithium battery 100 may include an electrode tab 70 illustrated in FIG. 5, which may form an electrical path for inducing the current formed in the electrode assembly 40 to the outside of the battery 100. FIG. 4 illustrates a positive electrode tab 71 and a negative electrode tab 72, the tabs 71 and 72 also forming an electrical path for inducing the current formed in the electrode assembly 40 to the outside of the battery 100.

The rechargeable lithium battery according to an example embodiment may be applicable to automobiles, mobile phones, and/or various types of electric devices, as non-limiting examples.

The following Examples and Comparative Examples are provided in order to highlight characteristics of one or more example embodiments, but it will be understood that the Examples and Comparative Examples are not to be construed as limiting the scope of the example embodiments, nor are the Comparative Examples to be construed as being outside the scope of the example embodiments. Further, it will be understood that the example embodiments are not limited to the particular details described in the Examples and Comparative Example.

### Example 1

Si particles were pulverized to prepare Si nano particles with an average particle diameter (D50) of 100 nm. The silicon nano particles with the average particle diameter (D50) of 100 nm and stearic acid were mixed at a weight ratio of 80:20 in an ethanol solvent using a ball mill for 1 hour at a speed of 1000 rpm to prepare a silicon particle liquid having a solid amount of 11 wt %.

The silicon particle liquid was spray-dried at 120° C. to prepare secondary particles where silicon nano particles (primary particles) were agglomerated.

A chemical vapor deposition (a gas flow rate: 100 sccm (which was a value measured at 0° C. and 1 atm) was conducted on the secondary particles using a SiH₄ gas at 470° C. for 20 minutes, thereby preparing a product including amorphous silicon positioned on the surface of the secondary particles.

Thereafter, the resulting product and meso carbon pitch were mixed at a weight ratio of 62.5:37.5, and the resulting mixture was heat-treated at 700° C. to prepare a negative active material.

The prepared negative active material included secondary particles where the crystalline silicon primary particles were agglomerated, the amorphous silicon surrounding the surface of the secondary particles, and a soft carbon coating layer between the secondary particles and on the surface of the amorphous silicon. In the prepared negative active material, a mixing ratio of the crystalline silicon primary particles and the amorphous silicon was in a weight ratio of 80:20, and based on 100 wt % of the negative active material, an amount of the crystalline silicon primary particles was 50.0 wt %, an amount of the amorphous silicon was 12.5 wt %, and an amount of the amorphous carbon was 37.5 wt %. The negative active material had a porosity of 0.5% and the soft carbon coating layer had a thickness of 50 nm.

The negative active material was used as a first negative active material, 97.5 wt % of a mixed negative active material of the first negative active material and the natural graphite second negative active material (a mixing ratio of the first and second negative active materials is equal to 10:90 weight ratio), 1.5 wt % of carboxymethyl cellulose, and 1 wt % of a styrene butadiene rubber were mixed in a water solvent to prepare a negative active material layer slurry.

The negative active material layer slurry was coated on a Cu foil current collector, dried and pressurized to prepare a negative electrode including the current collector and a negative active material layer formed on the current collector.

96 wt % of a LiNi_{0.8}Co_{0.1}Mn_{0.1}O₂ positive active material, 2 wt % of a ketjen black, and 2 wt % of polyvinylidene fluoride were mixed in an N-methyl pyrrolidone solvent to prepare a positive active material layer slurry.

The positive active material slurry was coated on an Al foil current collector, dried and pressurized to prepare a positive electrode.

Using the negative electrode, the positive electrode, and an electrolyte, a full cell was fabricated by the general procedures. As the electrolyte, 1M LiPF₆ dissolved in a mixed solvent of ethylene carbonate and dimethyl carbonate (3:7 volume ratio) was used.

### Example 2

A negative active material was prepared by the same procedure as in Example 1, except that the chemical vapor deposition was carried out at 470° C. for 34 minutes, and in the negative active material, a mixing ratio of the crystalline silicon primary particles and the amorphous silicon was a weight ratio of 70:30, and based on 100 wt % of the negative active material, the amount of the crystalline silicon primary particles was 50.0 wt %, an amount of the amorphous silicon was 21.0 wt %, and an amount of the amorphous carbon was 29.0 wt %. The negative active material had a porosity of 1% and the soft carbon coating layer had a thickness of 50 nm.

A negative electrode and a full cell were fabricated by the same procedure as in Example 1 with a difference in using the negative active material as a first negative active material.

### Example 3

A negative active material was prepared by the same procedure as in Example 1, with a difference that the chemical vapor deposition was carried out at 470° C. for 32 minutes, and in the negative active material, a mixing ratio of the crystalline silicon primary particles and the amorphous silicon was a weight ratio of 70:30, and based on 100 wt % of the negative active material, the amount of the crystalline silicon primary particles was 47.0 wt %, an amount of the amorphous silicon was 20.0 wt %, and an amount of the amorphous carbon was 33.0 wt %. The negative active material had a porosity of 1% and the soft carbon coating layer had a thickness of 50 nm.

A negative electrode and a full cell were fabricated by the same procedure as in Example 1 with a difference in using the negative active material as a first negative active material.

### Example 4

A negative active material was prepared by the same procedure as in Example 1, with a difference that the chemical vapor deposition was carried out at 470° C. for 50 minutes, and in the negative active material, a mixing ratio of the crystalline silicon primary particles and the amorphous silicon was a weight ratio of 60:40, and based on 100 wt % of the negative active material, the amount of the crystalline silicon primary particles was 47.0 wt %, an amount of the amorphous silicon was 31.0 wt %, and an amount of the amorphous carbon was 22.0 wt %. The negative active material had a porosity of 0.6%, and the soft carbon coating layer had a thickness of 50 nm.

A negative electrode and a full cell were fabricated by the same procedure as in Example 1 with a difference in using the negative active material as a first negative active material.

### Comparative Example 1

Si particles were pulverized to prepare Si nano particles with an average particle diameter (D50) of 200 nm. The silicon nano particles with the average particle diameter (D50) of 200 nm and stearic acid were mixed at a weight ratio of 90:10 in an ethanol solvent using a ball mill for 1 hour at a speed of 1000 rpm to prepare a silicon particle liquid having a solid amount of 11 wt %.

The silicon particle liquid was spray-dried at 120° C. to prepare secondary particles where silicon nano particles (primary particles) were agglomerated.

The secondary particle was mixed with meso carbon (pitch) at a weight ratio of 62.5:37.5 and the mixture was heat-treated at 950° C. to prepare a negative active material.

The prepared negative active material included secondary particles where the crystalline silicon primary particles were agglomerated and a soft carbon coating layer between the secondary particles and on the surface of the secondary particles. In the prepared negative active material, based on 100 wt % of the negative active material, an amount of the crystalline silicon primary particles was 62.5 wt %, and an amount of the amorphous carbon was 37.5 wt %. The negative active material had a porosity of 3.5%, and the soft carbon coating layer had a thickness of 50 nm.

A negative electrode and a full cell were fabricated by the same procedure as in Example 1 with a difference in using the negative active material as a first negative active material.

### Comparative Example 2

Si particles were pulverized to prepare Si nano particles with an average particle diameter (D50) of 200 nm.

The Si nano particles were mixed with meso carbon and the resulting mixture was heat-treated at 950° C. to prepare an agglomerated product of Si nano particles and soft carbon, and a chemical vapor deposition (a gas flow rate: 100 sccm (which was a value measured at 0° C. and 1 atm) was then performed on the agglomerated product using a SiH₄ gas at 470° C. for 20 minutes, thereby preparing a negative active material including amorphous silicon on the surface of the agglomerated product. Herein, a weight ratio of the crystalline Si nano particles, the amorphous carbon, and the amorphous Si on the surface was 50.0:37.5:12.5.

The prepared negative active material included an agglomerated product where the Si nano particles and soft carbon were agglomerated, and an amorphous silicon coating layer on the surface of the agglomerated product.

In the prepared negative active material, a mixing ratio of the crystalline silicon primary particles and the amorphous silicon was a weight ratio of 80:20, and based on 100 wt % of the negative active material, an amount of the crystalline silicon primary particles was 50.0 wt %, an amount of the amorphous silicon was 12.5 wt %, and an amount of the amorphous carbon was 37.5 wt %. The negative active material had a porosity of 4.7% and the amorphous silicon coating layer had a thickness of 20 nm.

A negative electrode and a full cell were fabricated by the same procedure as in Example 1 with a difference in using the negative active material as a first negative active material.

### Comparative Example 3

Si particles were pulverized to prepare Si nano particles with an average particle diameter (D50) of 200 nm. The silicon nano particles with the average particle diameter (D50) of 200 nm and stearic acid were mixed at a weight ratio of 90:10 in an ethanol solvent using a ball mill for 1 hour at a speed of 1000 rpm to prepare a silicon particle liquid having a solid amount of 11 wt %.

The silicon particle liquid was spray-dried at 120° C. to prepare secondary particles where silicon nano particles (primary particles) were agglomerated.

A chemical vapor deposition (a gas flow rate: 100 sccm (which was a value measured at 0° C. and 1 atm)) was conducted on the secondary particles using a SiH₄ gas at 470° C. for 32 minutes, thereby preparing a negative active material including amorphous silicon positioned on the surface of the secondary particles.

The prepared negative active material included secondary particles where the crystalline silicon primary particles were agglomerated, and the amorphous silicon surrounding the surface of the secondary particles. In the prepared negative active material, a mixing ratio of the crystalline silicon primary particles and the amorphous silicon was a weight ratio of 80:20, and based on 100 wt % of the negative active material, an amount of the crystalline silicon primary particles was 80 wt % and an amount of the amorphous silicon was 20 wt %. The negative active material had a porosity of 11.0%.

A negative electrode and a full cell were fabricated by the same procedure as in Example 1, with a difference in using the negative active material as a first negative active material.

### Experimental Example 1) Evaluation of X-Ray Diffraction

Regarding the first negative active materials according to Examples 1 to 4 and Comparative Examples 1 to 3, an X-ray diffraction analysis was carried out by using a CuKα ray.

The X-ray diffraction analysis was measured by using X'Pert (available from PANalytical B.V.) XRD equipment, but monochromator equipment was removed in order to improve peak intensity resolution. The measurement was performed under a condition of 2θ=20° to 80°, a scan speed (°/S)=0.06436, and a step size of 0.026°/step.

### Experimental Example 2) Evaluation of Porosity

The porosity of the first negative active materials according to Examples 1 to 4 and Comparative Examples 1 to 3 was measured through N₂ absorption isotherm by BJH (Barret-Joyner-Halenda) technique. The results are shown in Table 2.

### Experimental Example 3) Evaluation of Discharge Capacity

The full cells according to Examples 1 to 4 and Comparative Examples 1 to 3 were charged and discharged once at 1 C to measure a discharge capacity. The results are shown in Table 2.

### Experimental Example 4) Evaluation of Efficiency

The full cells according to Examples 1 to 4 and Comparative Examples 1 to 3 were charged and discharged once at 0.1 C to obtain a ratio of the measured discharge capacity relative to the measured charge capacity. The results are shown in Table 2, as efficiency.

### Experimental Example 5) Evaluation of Cycle-Life Characteristic

The half-cells according to Examples 1 to 4 and Comparative Examples 1 to 3 were charged and discharged at 1 C for 400 cycles. A ratio of discharge capacity at 400^{th} cycle relative to discharge capacity at 1^{st} cycle was calculated. The results are shown in Table 2, as capacity retention.

The conditions for the deposition and the compositions of the first negative active materials of Examples 1 to 4 and Comparative Examples 1 to 3 are shown in Table 1.

TABLE 1

| | | | Amount of | Amount of | |
|---|---|---|---|---|---|
| | Deposition | Crystalline:amorphous | crystalline Si | amorphous | Amount of |
| | condition | (weight ratio) | (wt %) | Si (wt %) | carbon (wt %) |
| Example 1 | 470° C., 20 | 80:20 | 50.0% | 12.5% | 37.5% |
| | minutes | | | | |
| Example 2 | 470° C., 34 | 70:30 | 50.0% | 21.0% | 29.0% |
| | minutes | | | | |
| Example 3 | 470° C., 32 | 70:30 | 47.0% | 20.0% | 33.0% |
| | minutes | | | | |
| Example 4 | 470° C., 50 | 60:40 | 47.0% | 31.0% | 22.0% |
| | minutes | | | | |
| Comparative | — | 100:0 | 62.5% | 0.0% | 37.5% |
| Example 1 | | | | | |
| Comparative | 470° C., 20 | 80:20 | 50.0% | 12.5% | 37.5% |
| Example 2 | minutes | | | | |
| Comparative | 470° C., 32 | 80:20 | 80.0% | 20.0% | 0.0% |
| Example 3 | minutes | | | | |

TABLE 2

| | Porosity | Discharge capacity | Efficiency | Capacity |
|---|---|---|---|---|
| | (%) | (mAh/g) | (%) | retention (%) |
| Example 1 | 0.5% | 505 | 90 | 93 |
| Example 2 | 0.5% | 509 | 91 | 94 |
| Example 3 | 0.5% | 504 | 90 | 94 |
| Example 4 | 0.6% | 512 | 91 | 94 |
| Comparative | 3.5% | 500 | 87 | 91 |
| Example 1 | | | | |
| Comparative | 4.7% | 503 | 85 | 85 |
| Example 2 | | | | |
| Comparative | 11.0% | 513 | 83 | — |
| Example 3 | | | | |

As shown in Table 2, the cells including the negative active materials of Examples 1 to 4 exhibited high discharge capacity, and desired or improved efficiency and capacity retention.

The cell of Comparative Example 1 including the negative active material only including the crystalline silicon and the amorphous carbon coating layer exhibited all deteriorated discharge capacity, efficiency, and capacity retention. The cell of Comparative Example 2 including the amorphous silicon coating layer formed on the agglomerated product of the crystalline silicon and the amorphous carbon exhibited slightly improved discharge capacity, but substantially deteriorated efficiency and capacity retention, compared to Comparative Example 1. The cell according to Comparative Example 3 including the negative active material without the amorphous carbon coating layer exhibited high discharge capacity, but substantially deteriorated efficiency, and cycle-life characteristic may be not measured.

While this disclosure has been described in connection with what is presently considered to be practical example embodiments, it is to be understood that the disclosure is not limited to the disclosed example embodiments, but, on the contrary, is intended to cover various modifications and equivalent arrangements included within the spirit and scope of the appended claims.

What is claimed is:

1. A negative active material, comprising:
crystalline silicon primary particles;
amorphous silicon; and
an amorphous carbon coating layer.

2. The negative active material as claimed in claim 1, wherein the amorphous silicon is on a surface of the crystalline silicon primary particles.

3. The negative active material as claimed in claim 1, wherein the amorphous carbon coating layer surrounds the crystalline silicon primary particles and the amorphous silicon.

4. The negative active material as claimed in claim 1, wherein the amorphous silicon surrounds a surface of the crystalline silicon primary particles.

5. The negative active material as claimed in claim 1, further comprising secondary particles, wherein:
the crystalline silicon particles are agglomerated,
the amorphous silicon is on a surface of the secondary particles, and
the amorphous carbon coating layer surrounds the amorphous silicon.

6. The negative active material as claimed in claim 1, wherein a mixing ratio of the crystalline silicon primary particles to the amorphous silicon is in a range of about 95:5 to about 20:80 by weight ratio.

7. The negative active material as claimed in claim 1, wherein an amount of the amorphous silicon is in a range of about 1 wt % to about 50 wt % based on 100 wt % of the negative active material.

8. The negative active material as claimed in claim 1, wherein an amount of the crystalline silicon primary particles is in a range of about 30 wt % to about 80 wt % based on 100 wt % of the negative active material.

9. The negative active material as claimed in claim 1, wherein the amorphous carbon coating layer has a thickness in a range of more than about 0 nm and about 2 μm or less.

10. The negative active material as claimed in claim 1, wherein the crystalline silicon primary particles have an average particle diameter (D50) in a range of about 50 nm to about 150 nm.

11. The negative active material as claimed in claim 1, wherein the negative active material has a porosity in a range of about 0% to about 3%.

12. The negative active material as claimed in claim 1, wherein the amorphous silicon is prepared by a vapor deposition.

13. The negative active material as claimed in claim 12, wherein the vapor deposition is carried out using a Si-included gas comprising at least one of a SiH₄ gas, a Si₂H₆ gas, and a Si₃H₈ gas.

14. The negative active material as claimed in claim 12, wherein the vapor deposition is a chemical vapor deposition.

15. The negative active material as claimed in claim 13, wherein in the vapor deposition process, the Si-included gas flow rate is in a range of about 1 sccm to about 1000 sccm.

16. The negative active material as claimed in claim 12, wherein the vapor deposition is carried out for a period in a range of about 10 minutes to about 5 hours.

17. A rechargeable lithium battery, comprising:
a negative electrode comprising the negative active material of claim 1;
a positive electrode; and
an electrolyte.

18. The rechargeable lithium battery as claimed in claim 17, wherein the negative electrode further comprises a crystalline carbon negative active material.
